(19) United States
(12) Patent Application Publication
(10) Pub. No.: US 2012/0194408 A1
(43) Pub. Date: Aug. 2, 2012

(54) Device Comprising an Antenna

(75) Inventor: Hannu Juhani RAJALIN, Nokia (FI)

(73) Assignee: NOKIA CORPORATION, Espoo (FI)

(21) Appl. No.: 13/359,477

(22) Filed: Jan. 26, 2012

(30) Foreign Application Priority Data
Jan. 26, 2011 (GB) 1101312.5

(51) Int. Cl. G01R 29/08; H01P 11/00

(52) U.S. Cl. 343/894; 29/600

(57) ABSTRACT

A device comprises an antenna configured for near field communication with a remote antenna, the antenna producing a magnetic field when in operation, and a light source operable to project light from the device, the light source being arranged within the device so as to indicate, when illuminated, a first direction in which the magnetic flux density of the field produced by the antenna is sufficiently large to allow near field communication with the remote antenna.

### FIELD OF THE INVENTION

The invention relates to a device comprising an antenna. In particular, the invention relates to a device comprising an antenna configured for near field communication.

### BACKGROUND TO THE INVENTION

Radio Frequency Identification (RFID) is a technology that uses communication via radio waves to allow communication between an initiator device (sometimes referred to as a reader device) and a target device (sometimes referred to as a tag).

Ultra-High Frequency (UHF) RFID, which operates using frequencies in the region of 1 GHz, allows communication between initiator device and target device that are separated by a distance of up to approximately 10 metres (this can be increased if the target device is provided with a power source). This type of RFID operates by the initiator device emitting a radio frequency (RF) signal from an antenna. The target device, which also includes an antenna, detects the RF signal and responds by emitting its own RF signal, which is subsequently detected by the initiator device.

Another type of RFID is near field communication (NFC). This operates using frequencies in the range of tens of MHz and typically allows communication between an initiator device and a target device that are separated by a distance of up to approximately 10 centimetres. As in UHF RFID, initiator and target devices which are suitable for NFC each include an antenna. Unlike in UHF RFID however, NFC operates using inductive coupling between the antennas of each device. Inductive coupling occurs when a magnetic field produced by the antenna of the initiator device passes through the antenna of the target device. This causes a current to flow in the antenna of the target device, the current being interpreted by the logic of the target device.

There are two modes of NFC: passive communication mode and active communication mode. In the passive communication mode, the initiator device provides a carrier field and the target device answers by modulating the existing field. In this mode, the target device may draw its operating power from the initiator-provided electromagnetic field, thus making the target device a transponder. In active communication mode, both initiator and target device communicate by alternately generating their own fields. A device deactivates its RF field while it is waiting for data. In this mode, both devices typically have power supplies.

The invention is concerned with devices, such as NFC devices, that communicate using inductive coupling.

Unlike, UHF RFID, NFC is highly sensitive to the relative orientations of the initiator and target devices. This is because the strength of inductive coupling occurring between two antennas is dependent on both the angle at which the magnetic field due to the antenna of the initiator device cuts the antenna of the target device and the magnetic flux density when the field cuts the target devices antenna. For optimum coupling, the field lines should cut the turns of the antenna at 90 degrees. The further the angle is from 90 degrees, the weaker the inductive coupling between the two antennas. Also, as the flux density of the field when it cuts the target device's antenna increases, so to does the inductive coupling that occurs.

FIGS. 1A and 1B are schematic illustrations of a prior art NFC device. The device 1, which in this example happens to be mobile telephone, comprises is an antenna 10. The antenna 10 comprises a planar coil of conductive material. The antenna 10 is provided substantially parallel to the planes of the main external surfaces 12, 14 of the device 1. As such the direction of maximum magnetic flux density (which is denoted by arrow A) is perpendicular to the planes of main external surfaces 12, 14 of the device 1.

Typically, other NFC devices with which the device 1 is configured to communicate, for example NFC readers in transport systems, also include a planar coil antenna located parallel and proximate to an exterior surface. As such, the user of the device 1, in order to ensure maximum inductive coupling between the two devices, should place one of the main surfaces 12, 14 of the device 1 against the exterior surface of the device with which communication is to occur.

However, as portable devices, such as mobile telephones, become more advanced, the need for efficient use of space within the devices becomes increasingly important. As such, device designers have been looking for ways in which to incorporate NFC antennas into devices in a more space-efficient manner. One way in which this has been done is by wrapping the NFC antenna around other existing components of the device, instead of by providing the antenna in a planar manner on a flat surface within the device. These other components may include audio components, such as a speaker cavity, or other antenna components such as the main telephone antenna, which is typically provided at one end of the device. U.S. Ser. No. 12/455,751 describes a combined NFC and GSM/WCDMA assembly, which allows a more efficient use of space within a mobile telephone. It will be appreciated that antenna such as this may take any appropriate shape and as such may not be symmetrical.

One consequence of not providing the NFC antenna parallel to a main surface of the device is that the direction of maximum magnetic flux density may no longer be perpendicular to the main surface.

### SUMMARY OF THE INVENTION

In a first aspect, this specification describes a device comprising an antenna configured for near field communication with a remote antenna, the antenna producing a magnetic field when in operation. The device also comprises a light source operable to project light from the device, the light source being arranged within the device so as to indicate, when illuminated, a first direction in which the magnetic flux density of the field produced by the antenna is sufficiently large to allow near field communication with the remote antenna.

The specification also describes a device comprising an antenna configured for near field communication with a remote antenna, the antenna producing a magnetic field when in operation. The device also comprises a light source operable to project light from the portable device, the light source being arranged within the device so as to indicate, when illuminated, a direction of maximum magnetic flux density of the field produced by the antenna.

The term “direction of maximum magnetic flux density” is intended to include also directions in which the magnetic flux density is substantially at a maximum, as long as benefits of the invention are obtained.

In another aspect, this specification describes a method of manufacture of a device, the method comprising providing an antenna within the device, the antenna being configured for communication with a remote antenna and producing a magnetic field when in operation, providing a light source within the device, the light source being operable to project light from the device, and arranging the light source within the device such that the light source indicates, when illuminated, a direction in which the magnetic flux density of the field produced by the antenna is sufficiently large to allow near field communication with the remote antenna.

### BRIEF DESCRIPTION OF THE FIGURES

FIGS. 1A and 1B are schematic illustrations of a prior art device;

FIG. 2 is a schematic block diagram of a device according to embodiments of the invention;

FIGS. 3A and 3B are simplified illustrations of an end portion of the device of FIG. 2; and

FIG. 4 is a flow chart illustrating a method of manufacture of the device of FIG. 2.

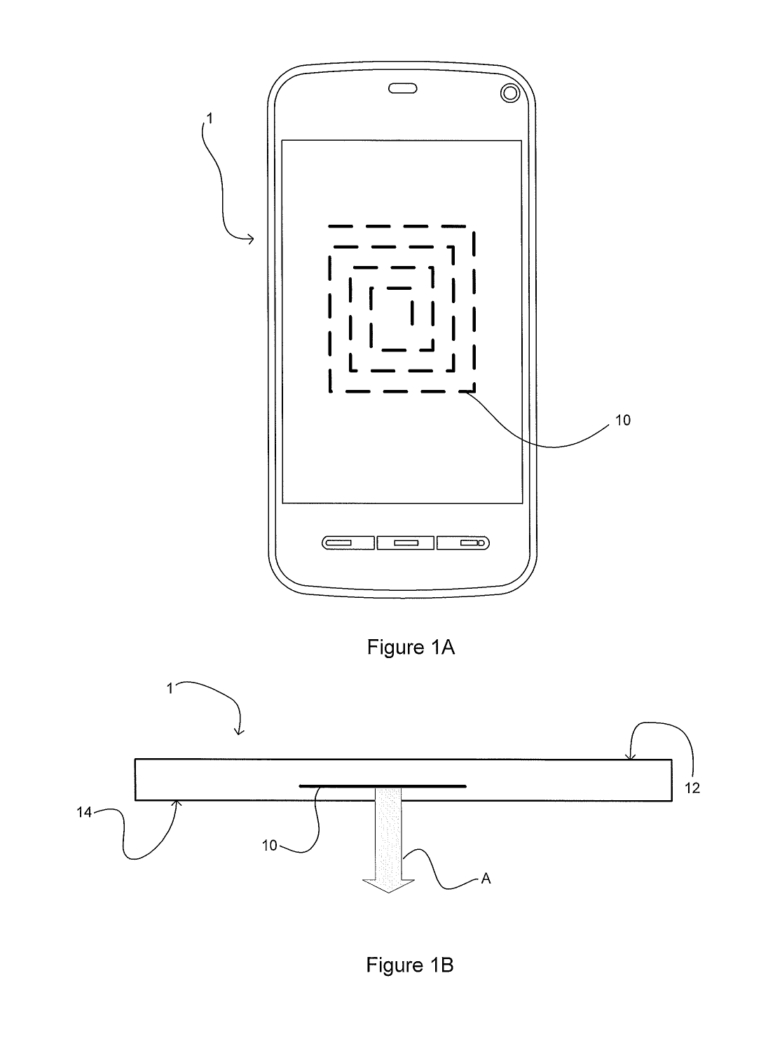

### DETAILED DESCRIPTION OF EMBODIMENTS

In the drawings and the following description, like reference numerals refer to like elements throughout.

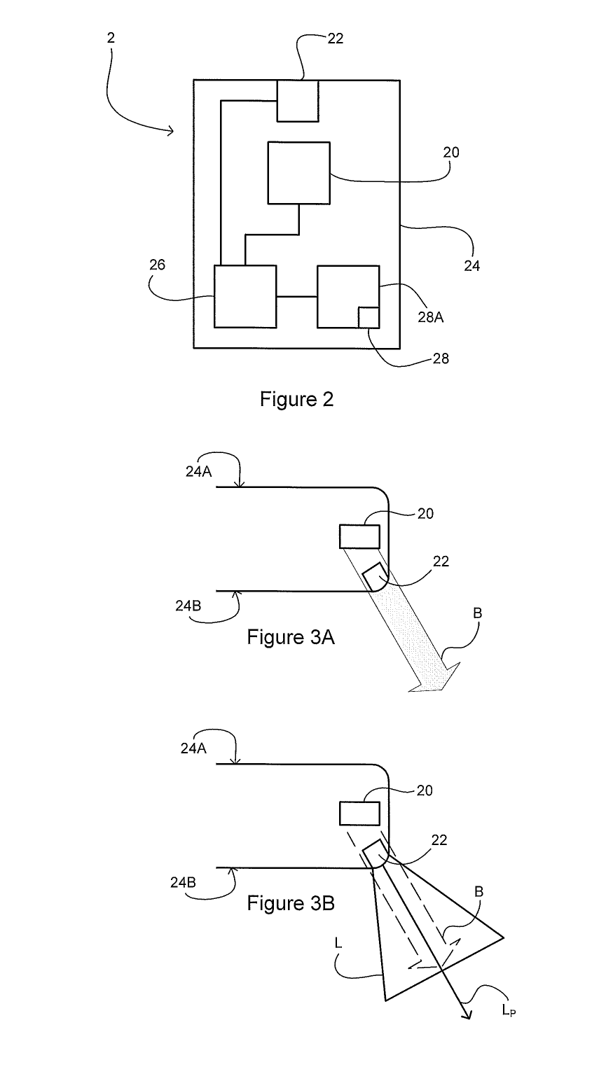

FIG. 2 is a schematic block diagram of a device according to embodiments of the invention. In the example embodiment of FIG. 2, the device 2 comprises an NFC antenna 20, a light source 22, a housing 24, a controller 26 and a memory 28.

The antenna 20 is configured for enabling the device 2 to communicate via NFC with other NFC devices. The light source 22 is configured to project light outwards from the housing 24 of the device 2. The controller 26 is configured to control the operation of the antenna 20 and light source 22. The controller 26 operates under the controller of computer readable code 28A stored on the memory 28. The controller 26 may comprise any combination of processors, microprocessors and application specific integrated circuits. It will be understood that the device 2 may also contain other components (not shown) dependent on its function. For example, in embodiments in which the device 2 is a mobile telephone, the device comprises other components for allowing it to function as such. According to alternative example embodiments, the device 2 may be an audio player, an e-reader, or another type of portable device.

FIGS. 3A and 3B are simplified illustrations of an end portion of device 2. As can be seen in the example of FIG. 3A, the antenna 20 is arranged within the device such that the direction of maximum magnetic flux density due to current passing through the antenna is not perpendicular to either of the main surfaces, such as the front and the back surfaces 24A, 24B, of the housing 24. In other words, the direction of maximum magnetic flux density is forms an acute angle with the plane of the main surfaces. As described above, this may be so as to allow a more space efficient arrangement of components within the housing 24. In FIG. 3A, the direction of maximum magnetic flux density due to the antenna 20 is depicted by the arrow B.

The light source 22 is arranged relative to the NFC antenna 20 such that, when it is illuminated, it provides an indication as to the direction of maximum magnetic flux density. This is achieved by the light source being arranged to project light in the direction of maximum magnetic flux density. More specifically, the principal axis of the light projected from the device is aligned or with the direction of maximum magnetic flux density. The principal axis refers to the axis about which light projected from the device is symmetrically distributed. This can be seen in FIG. 3B, in which the light projected by the light source 22 is labelled L, with the principal axis being labelled L_{P}. It will be appreciated that in this specification the term “aligned” allows for a small amount of error in alignment.

Alignment of the principal axis L_{P} of the light source with the direction of maximum magnetic flux density may be achieved by orientating the light source 22 itself with the direction of maximum magnetic flux density. Alternatively, one or more optical elements (not shown), such as lenses, may be utilised to achieve this effect.

In the above, the light source 22 is arranged within the device 2 so as to indicate, when illuminated, the direction of maximum magnetic flux density of the field produced by the antenna. However, it will be appreciated that in some instances it may not be possible and/or desirable for the light source to indicate the direction of maximum magnetic flux density. As such, the light source may instead indicate a direction in which the magnetic flux density is sufficiently large to allow near field communication with the target antenna. Although near field communication also depends on a number of factors other than flux density of the field due to the antenna of the initiator device (such as the configuration and orientation of the target antenna and interference etc.) it will be appreciated that unless the flux density is sufficiently large, it is not possible to establish near field communication, regardless of the aforementioned other factors. Thus, the light source is arranged to indicate a direction in which the magnetic flux density is sufficiently large to make near field communication possible. The threshold for whether or not the flux density is sufficiently large may be determined using a set of assumptions based on common configurations of NFC antennas that are currently used in the public domain. Likewise, an assumption of an average interference may also be used. It will of course be appreciated that the direction of maximum magnetic flux density is a direction in which the magnetic flux density is sufficiently large to allow near field communication with the target antenna.

The controller 26 is configured to cause the light source to be illuminated (or switched on) when the device is to be used for NFC. This may be triggered in any suitable way, for example in response to a user input via a user interface (not shown) or automatically in response to detection of a magnetic field generated by the target device.

The provision of a light source aligned as described above and illuminated when NFC is to be carried out provides an indication to the user as to how they should orientate the device 2 in relation to devices with which it is communicating. In order to achieve maximum inductive coupling, the user should orientate the device 2 such that the principal axis L_{P} is perpendicular to the antenna of the target device. The user is able to determine when the principal axis L_{P} based on the appearance of the light spot produced on the target device. When the spot is substantially circular, the user knows that the device is correctly oriented. It may not be necessary to orientate the device 2 such that direction of magnetic field is substantially perpendicular to the antenna of the target device. Instead, in some instances it may be sufficient that the light from the light source is directed such that projected light falls on the antenna of the target device, regardless of whether or not the principal axis L_{P} is substantially perpendicular to the antenna of the target device.

In some embodiments, the device 2 acts as the target device in communication with another device which acts as the initiator device. In such embodiments, the position of the light source 22 acts as a reference point for the user of the initiator device, relative to which they should orientate their device. The light source 22 itself indicates the position of the antenna 20. The projected provides further information to the user of the initiator device regarding how the initiator device should be orientated relative to the light source.

Some light sources project light in a relatively wide arc. As such, in order to obtain a narrower beam of projected light, and thereby to provide more accurate information to the user of the device 2, the light source 22 may be set (or provided) within an aperture (not shown in FIG. 2 or 3) formed in the housing 24. In this way, light which is projected from the light source 22 at angles which are far removed from the principal axis L_{P} is obstructed by the sides of the aperture within which the light source 22 is set and so is not projected from the device 2. Consequently, only light which is projected from the light source 22 at angles closer to the principal axis L_{P} are projected from the device 2 and so the projected beam is narrower. In some example embodiments, a light transitive material may be provided at the external end of the aperture. This may, for example, prevent moisture entering the device via the aperture. In some examples, the light transitive material may comprise a lens (not shown) to focus the projected light.

In some example embodiments, the light source 22 comprises a light emitting diode (LED). In other example embodiments, the light source 22 comprises a laser diode. It will be appreciated however, that the light source 22 may be of any suitable type.

In some example embodiments, the controller 26 is configured, under the control of computer-readable code 28A to cause the light source 22 to provide the user with additional information regarding an NFC session. In such embodiments, the controller 26 is configured to modulate the illumination of the light source in dependence on the status of the NFC session. For example, in a first mode, the controller 26 may be configured to modulate the brightness of the light projected by the light source depending on the strength of inductive coupling between the antenna 20 and the antenna of the other device. Thus, the controller 26 may cause the intensity of the projected light to increase as the strength of the inductive coupling increases. When the strength of inductive coupling reaches a level such that data transfer is able to commence, a second mode, in which the light source is caused to flash, or blink, may be initiated. The second mode may continue until the communication is complete, at which point the controller 26 may cause the light source to be switched off. If during communication, the orientation of the device 2 was inadvertently altered such that the communication can not continue, the controller 26 may switch back to the first mode. In this way, the user of the device is able to determine from the behaviour of the projected light the status of the NFC session. It will be appreciated that any other combination light source illumination modulation modes may be used to convey information regarding the NFC session to the user.

There are a number of ways in which the strength of the inductive coupling may be monitored. These include monitoring the current consumption of the NFC circuitry, monitoring the current induced by the inductive coupling or by measuring the strength of the RF field. The light source may be switched from the first mode to the second mode in response to detection of a first received bit of data.

In some example embodiments, the light source may comprise more than one light source, each of a different colour. In such embodiments, the controller may illuminate one or other of the light sources dependent of the status of the NFC session. For example, if the light sources were red and green, the red light source may be illuminated when the inductive coupling is not sufficiently strong to allow data transfer and the green light source may be illuminated when data transfer is taking place. In other example embodiments, the above-described effect may be achieved by using a light source which is configured to emit light of more than one different colour. Examples of light sources such as this include bi- and tri-LEDs, which are capable of emitting light in two and three different colours respectively.

In other example embodiments, a display of the device may be controlled so as to provide the indication of the status of the NFC session.

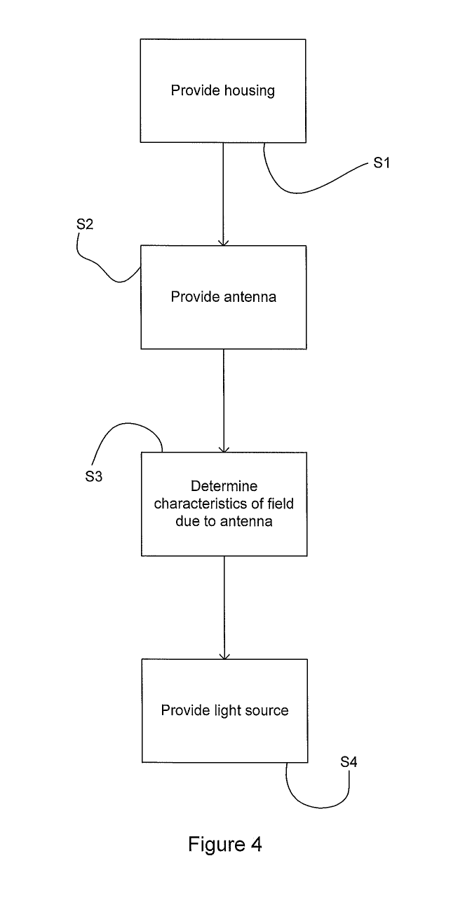

FIG. 4 is a flow chart depicting an example method for manufacture of a device according to example embodiments of the invention.

In step S1, the housing 24 is provided. In step S2, the antenna 20 is provided within the housing. In step S3, the characteristics of the magnetic field that results from current passing through antenna 20 are determined. These may be determined in any suitable way, for example using any one of a number of known types of magnetometer to measure the magnetic field at various positions around the housing. In step S4, the light source 22 is provided within the housing in such a way that the light source indicates, when illuminated, a first direction in which the magnetic flux density of the field produced by the antenna is sufficiently large to allow near field communication with antenna of a target device. In some example embodiments, the principal axis L_{P} of light projected from the light source is aligned with the first direction. As described above, this may be achieved by aligning the light source itself, which may be an LED, with the first direction. Alternatively, a system of optical elements may be utilised to achieve this effect. As will be understood from above, in some example embodiments, the first direction is the direction of maximum magnetic flux density.

It will be appreciated that the steps of the above method may be performed in a different order. For example, the first direction may, and in many cases will, have been determined prior to the assembly of the device 2. As such, so long as the planned orientation of the antenna within the housing 24 is known, the light source 22 can be provided within the housing 24 before the antenna 20.

In the above-described example embodiments, the light source 22 projects light in a first direction in which the magnetic flux density of the field produced by the antenna is sufficiently large to allow near field communication with antenna of a target device. It will be appreciated, however, this first direction may be indicated in other ways. For example, the light source 22 may be configured to project more than one beam of light, with the first direction being along an axis that passes through a point falling between the more than one beam. Similarly, the light source 22 may be configured to project a ring of light, with the first direction being along an axis that passes through the area encompassed by the ring. It will also be appreciated that the beam may be shaped in any other way that provides an indication as to a direction in which the magnetic flux density of the field produced by the antenna is sufficiently large to allow near field communication with an antenna of a target device.

Devices according to example embodiments of the invention may be utilized to facilitate NFC between the device and various types of other entity. These other entities include infrastructural entities (such as entry and exit gates in mass transit systems and automatic telling machines), household appliances (such as heating boilers and washing machines, for example to provide software updates), and vehicle on-board computers etc. In addition, as will be appreciated from the above description, devices according to example embodiments of the invention can be used to facilitate NFC with portable devices such as mobile telephones and the like.

It should be realized that the foregoing embodiments should not be construed as limiting. Other variations and modifications will be apparent to persons skilled in the art upon reading the present application. Moreover, the disclosure of the present application should be understood to include any novel features or any novel combination of features either explicitly or implicitly disclosed herein or any generalization thereof and during the prosecution of the present application or of any application derived therefrom, new claims may be formulated to cover any such features and/or combination of such features.

What is claimed is:

1. A device comprising:
an antenna configured for near field communication with a remote antenna, the antenna producing a magnetic field when in operation; and
a light source operable to project light from the device, the light source being arranged within the device so as to indicate, when illuminated, a first direction in which the magnetic flux density of the field produced by the antenna is sufficiently large to allow near field communication with the remote antenna.

2. A device as in claim 1, wherein the light source is arranged within the device so as to project light from the device in the first direction, thereby to allow the light source to indicate the direction in which the magnetic flux density of the field produced by the antenna is sufficiently large to allow near field communication with the remote antenna.

3. A device as in claim 2, wherein a principal axis of the light projected from the device is aligned with the first direction, thereby to allow the light source to indicate the direction in which the magnetic flux density of the field produced by the antenna is sufficiently large to allow near field communication with the remote antenna,
or wherein the light source is orientated in the first direction,
or wherein the first direction is the direction of maximum magnetic flux density,
or when the device comprising:
a housing having a front face and a back face, wherein the antenna is arranged within the housing such that a direction of maximum magnetic flux density is at an acute angle to said front and back faces,
or the device wherein the light source is located within an aperture formed in the housing.

4. A device as in claim 2, wherein the light source is a light emitting diode,
or wherein the light source is a laser diode.

5. A device as in claim 2, comprising a controller configured to determine when the antenna is in communication with the remote antenna, the controller configured to cause the light source to operate in a first mode when the antenna is in communication with the remote antenna, and configured to cause the light source to operate in a second mode when the antenna is not in communication with the remote antenna.

6. A method of manufacture of a device, the method comprising:
providing an antenna within the device, the antenna being configured for communication with a remote antenna and producing a magnetic field when in operation;
providing a light source within the device, the light source being operable to project light from the device; and
arranging the light source within the device such that the light source indicates, when illuminated, a direction in which the magnetic flux density of the field produced by the antenna is sufficiently large to allow near field communication with the remote antenna.

7. A method as in claim 6, comprising arranging the light source within the device so as to project light from the device in the first direction, thereby to allow the light source to indicate the direction in which the magnetic flux density of the field produced by the antenna is sufficiently large to allow near field communication with the remote antenna.

8. A method as in claim 7, comprising arranging the light source within the device such that a principal axis of the light projected from the device is aligned with the first direction, thereby to allow the light source to indicate the direction in which the magnetic flux density of the field produced by the antenna is sufficiently large to allow near field communication with the remote antenna,
or wherein the first direction is the direction of maximum magnetic flux density,
or comprising arranging the antenna within the housing such that a direction of maximum magnetic flux density is at an acute angle to front and back faces of the housing,
or comprising locating the light source within an aperture formed in the housing.

9. A method as in claim 7, comprising providing within the housing a controller configured to determine when the antenna is in communication with the remote antenna, the controller configured to cause the light source to operate in a first mode when the antenna is in communication with the remote antenna, and configured to cause the light source to operate in a second mode when the antenna is not in communication with the remote antenna.
